(19) United States
(12) Patent Application Publication
(10) Pub. No.: US 2010/0012036 A1
(43) Pub. Date: Jan. 21, 2010

(54) ISOLATION FOR MULTI-SINGLE-WAFER PROCESSING APPARATUS

(76) Inventors: Hugo Silva, Cologne (DE); Martin Dauelsberg, Aachen (DE); Johannes Lindner, Rott (DE); Thomas E. Seidel, Palm Coast, FL (US); Gerhard K. Strauch, Aachen (DE)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(21) Appl. No.: 12/502,142

(22) Filed: Jul. 13, 2009

Related U.S. Application Data
(60) Provisional application No. 61/080,224, filed on Jul. 11, 2008.

(51) Int. Cl. C23C 16/46; C23C 16/00

(52) U.S. Cl. 118/725; 118/715

(57) ABSTRACT

An MSW processing apparatus includes two or more semi-isolated reaction chambers separated from one another by isolation regions configured with two or more TIG elements, either or both of which may be independently purged. The TIG elements may be configured in a staircase-like fashion and include vertical and horizontal conductance spacings, sized so that, under different operational process temperatures of the MSW processing apparatus, a change in the horizontal conductance spacing is less than a change in the vertical conductance spacing.

### CROSS-REFERENCE TO RELATED APPLICATIONS

This application is a non-provisional of, claims priority to, and incorporates by reference U.S. Provisional Patent Application 61/080,224, filed 11 Jul. 2008.

### BACKGROUND OF THE INVENTION

The present invention relates to methods and systems for providing isolation between reaction spaces or chambers within a multi-chamber processing unit of a semiconductor wafer processing station or similar apparatus.

U.S. patent application Ser. No. 11/780,698 and International Application PCT/US06/61201, each of which is assigned to a common owner of the present invention and incorporated herein by reference, describe wafer processing apparatus having multiple single wafer reaction chambers, one or more of which contain a vertically moveable heater-susceptor with an attached, annular flow ring conduit at its perimeter. The annular flow ring conduit has an external surface at its edge that isolates the outer space of the reaction chamber above a wafer positioned on the heater-susceptor from a confined reaction space when the heater-susceptor is in a process (higher) position with respect to a loading (lower) position. This is accomplished by the outer edge of the annular flow ring being brought into proximity with an annular ring attached to a lid of the reactor. Together, these units form a tongue-in-groove (TIG) configuration, in some cases with a staircase contour, thereby limiting diffusion-backflow of downstream gases to the outer space of the reactor.

An example of this configuration is shown in FIG. 1, which illustrates a portion of a single wafer reaction chamber 10 for a wafer processing apparatus. The heater-susceptor is not shown in this view, however, the outer edge 12 of the annular flow ring that is attached to the heater-susceptor at its periphery is illustrated. In this illustration, the heater-susceptor is assumed to be in its processing (or upper) position, and a portion of the outer edge 12 of the annular flow ring resides between an inner portion 14A and an outer portion 14B of a lid ring 14, forming a TIG configuration. The lid ring 14 is attached to a lid 16 of the reactor and a filleted member 18 is positioned inwardly of the inner portion 14A of the lid ring so as to deflect gasses within the inner reaction space 20A. The TIG configuration of the outer edge of the annular flow ring 12 and the lid ring 14 acts to prevent diffusive back flow from the outer reaction space 20B to the inner reaction space 20A.

Further, in this illustrated example, the outer edge 12 of the annular flow ring is notched so that a portion of this outer edge 12 underlaps the inner portion 14A of the lid ring. Thus, a staircase-like assembly is formed. This staircase TIG configuration improves the isolation between the inner and outer reactions spaces 20A and 20B over that which would be achieved by a TIG configuration alone. This staircase-TIG design also addresses mechanical thermal expansion issues (dominated by radial expansion) that may otherwise make the tolerances required in a TIG design difficult to practically maintain.

Doering, U.S. PGPUB 2002/0108714, which is assigned to a common owner of the present invention, describes a reaction chamber having a vertically movable susceptor with an attached flow ring that is used to isolate a wafer transport load lock area from the reaction space. However, the isolation is achieved by mechanical contact of the flow ring with an interior ring surface, and this design allows for circulation of precursors. The design also does not permit a minimal reaction space volume. The above-cited U.S. patent application Ser. No. 11/780,698 and International Application PCT/US06/61201 rectify these limitations with the TIG isolation design that allows for a minimized reaction space without requiring mechanical contact.

Chiang, U.S. PGPUB 2005/0051100, describes techniques for achieving semi-isolation between reactors in a multi-reactor processing station, including designs employing a saw tooth configuration and a simple TIG configuration. However, a serious drawback of these proposals is that thermal radial expansion of the different reactors—referenced to the center of the processing system—can result in contact across a vertical gap in each of these isolation areas, compromising a design intent on non-contact isolation. The staircase-like TIG configuration described in U.S. patent application Ser. No. 11/780,698 and International Application PCT/US06/61201 overcomes this limitation, allowing radial expansion without contact of larger vertical surfaces while using the horizontal slot dimension of the TIG for minimal conductance.

The following references are also relevant to the present invention: U.S. Pat. Nos. 7,008,879; 6,827,789; 6,635,115; 6,576,062; 6,440,261; 6,152,070; 6,143,082; 5,882,165; 5,855,681, 5,685,914 and U.S. PGPUBs 2005/0034664, 2004/0261946, 2005/0016956 and 2005/0139160. As is apparent from these examples of conventional multi single wafer (MSW) systems, a number of approaches to achieving inter-reaction space isolation have been proposed. One example is a configuration with isolated single wafer reaction spaces, where the isolation is achieved by contact using an o-ring seal. See, e.g., U.S. PGPUB 2005/0034664 and U.S. Pat. Nos. 7,008,879 and 6,827,789. In other cases, the transfer indexer is left in place as part of the sealing surfaces. See, e.g., U.S. Pat. Nos. 7,008,879 and 6,827,789. In both such implementations the surface-on-surface contact within the isolation region results in disadvantageous particle generation and the adherence of the surfaces to one another in a vacuum environment.

In other configurations, see e.g., U.S. Pat. No. 5,855,681, the space between reaction zones is separated by simple plates or baffles and does not afford extremely small conductance between reaction spaces so that only minimal isolation between reaction zones is obtained. Still other configurations provide integration of single wafer reactors on a cluster platform (see, e.g., U.S. Pat. Nos. 6,440,261; 6,152,070 and 5,882,165). These configurations do not provide the productivity anticipated in the current MSW design nor do they include the isolation means described herein.

### SUMMARY OF THE INVENTION

Various embodiments of an MSW processing apparatus are herein provided. In some embodiments, the MSW processing apparatus may include two or more semi-isolated reaction chambers and a separate indexer volume. The reaction chambers may be separated from one another by isolation regions configured with two or more TIG elements, at least one of which may be configured in a staircase-like fashion. There may be one or more gas flow pathways through each TIG element. Each gas flow pathway through the TIG elements may be independently purged via an independent purge line. In some cases, purges through the independent purge lines are independently time controlled.

A TIG element may be configured in a staircase-like fashion and include vertical and horizontal conductance spacings. The vertical and horizontal conductance spacings may be sized so that, under different operational process temperatures of the MSW processing apparatus, a change in the horizontal conductance spacing is less than a change in the vertical conductance spacing. Additionally or alternatively, a TIG element configured in a staircase-like fashion may be operable to limit diffusion-backflow of a downstream gas to an outer chamber of the MSW apparatus.

In some cases, the MSW processing apparatus includes a pump that is operable to remove a gas stream through one or more of the independent purge lines.

In another embodiment, an MSW processing apparatus includes two or more semi-isolated reaction chambers and a separate indexer volume. The reaction chambers may be separated from one another by isolation regions that are configured with two or more TIG elements and may include an inner TIG element and an outer TIG element. The inner TIG element may include an annular flow ring.

One or more of the TIG elements may be configured in a staircase-like fashion. There may be one or more gas flow pathways through each TIG element. Each gas flow pathway through the TIG elements may be independently purged via an independent purge line.

Reaction chambers included in the MSW processing apparatus may include a vertically movable heater-susceptor coupled to the annular flow ring that is configured as a gas conduit and has an outlet port extending below a bottom of a wafer transport slot valve of the reaction chamber apparatus when the heater-susceptor is in a processing position.

In a further embodiment, the reaction chambers of an MSW processing apparatus may include a heater-susceptor coupled to an annular flow ring conduit at a perimeter of the heater-susceptor. The annular flow ring may be defined by inner and outer members and may be configured to isolate an outer chamber of at least one of the reaction chambers above a wafer position from a confined reaction chamber of the reaction chamber when the heater-susceptor is in a processing position.

An outer member of the annular flow ring may be in proximity with a second annular ring attached to a lid of the reaction chamber, the outer member of the annular flow ring and the second annular ring may form at least one of the TIG elements, wherein the inner TIG element includes the annular flow ring.

On some occasions, the MSW processing apparatus may also include a pump that is operable to remove gas through one or more of the independent purge lines.

In yet another embodiment, each of the reaction chambers may include a vertically movable susceptor coupled to an annular flow ring conduit at a perimeter of the susceptor. The annular flow ring conduit may be included in the inner TIG element and may be configured to pass reaction gas effluent to a downstream pump.

In some cases, the annular flow ring includes a lower orifice. On such occasions, the MSW processing apparatus may further include a downstream baffle located between the lower orifice of the annular flow ring and the downstream pump.

In one embodiment, a second annular ring may be attached to a lid of the reaction chamber apparatus. The second annular ring may be in proximity to an outer member of the annular flow ring conduit when the vertically movable susceptor is in a process position. The second annular ring and the outer member of the annular flow ring conduit may form one of the TIG configurations. The second annular ring may be an inner lid ring and, in this instance, the MSW processing apparatus may further include an outer lid ring surrounding the TIG configuration formed by the second annular ring and the outer member of the annular flow ring conduit when the vertically movable susceptor is in the process position. On some occasions, a joint between the second annular ring and the lid is curved. A joint between the second annular ring and the lid may also be filleted.

### BRIEF DESCRIPTION OF THE DRAWINGS

The present invention is illustrated by way of example, and not limitation, in the figures of the accompanying drawings, in which:

FIG. 1 illustrates a portion of a single wafer reaction chamber included in a wafer processing apparatus;

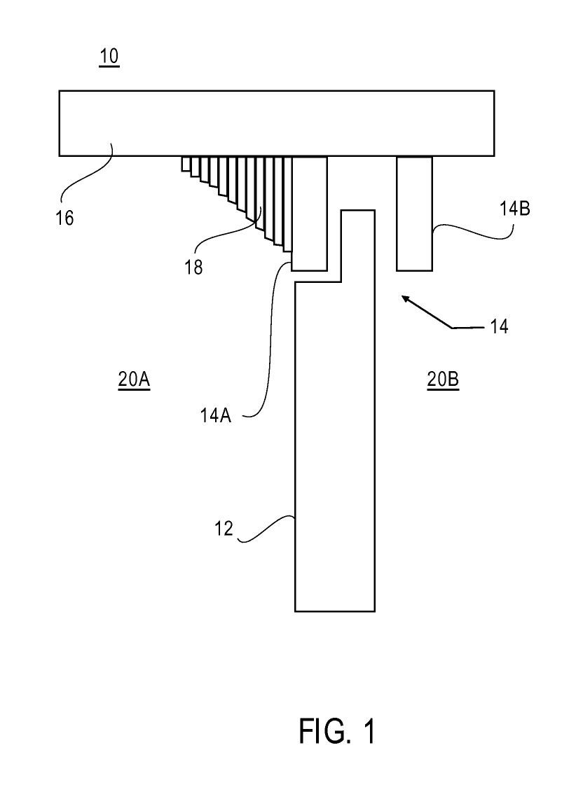

FIG. 2A shows an example of a portion of an MSW processing apparatus configured in accordance with an embodiment of the present invention;

FIG. 2B illustrates a cross section of a portion of an exemplary reaction chamber, consistent with an embodiment of the present invention;

FIG. 3 illustrates a cross section of an exemplary reaction chamber, consistent with an embodiment of the present invention;

FIG. 4 illustrates a cross section of portion of a reaction chamber, consistent with an embodiment of the present invention;

FIG. 5 illustrates a cross section of an exemplary purged, TIG configuration, consistent with an embodiment of the present invention; and

FIG. 6 illustrates horizontal and vertical spacings in an exemplary purged, TIG arrangement, consistent with an embodiment of the present invention.

### DETAILED DESCRIPTION

The present invention relates to methods and systems for providing isolation between reaction spaces or chambers within a multi-chamber processing unit of a semiconductor wafer processing station or similar apparatus. In one embodiment, the invention provides a high productivity, MSW processing apparatus suitable for cyclic deposition processes such as atomic layer deposition (ALD) and pulsed chemical vapor deposition (CVD) and including two or more semi-isolated reactors. In one instance, four such reactors are positioned radially about a common center and wafers are loaded by an indexer within a semi-isolated space in the process module housing the four reactors. These reaction chambers may be used for common deposition processes on wafers housed therein.

In order to obtain the state of semi-isolation between reaction chambers, each reaction chamber is configured with two or more TIG elements, at least one of which has a conformal staircase design, and either or both of which have an independently purged gas flow pathway through the TIG arrangement to ensure negligible back-diffusive chemical transport to the indexer space, process module housing and adjacent reaction spaces. Further, the staircase and TIG elements may be configured with vertical and horizontal spacings such that a change in the horizontal spacing due to, for example, thermal expansion may be less than a change in the vertical spacing, thus enabling different operational process temperatures of the MSW apparatus, and ensuring non-contact, semi-isolation over a wide temperature range.

Purges in one (or both) of the TIG spacings may be time controlled and independent in order to optimize process conditions such as reaction space pressure (as exemplified in time phased multilevel flow (TMF) operation, see e.g., U.S. patent application Ser. No. 10/791,030, filed 1 Mar. 2004, assigned to a common owner of the present invention) and control of diffusive transport outside the reaction space, in particular to minimize transport to the indexer space. Additionally, diffusive transport to the indexer regions and process module housing is less than 1E-10 the precursor concentration in the reaction space, and without surface-to-surface contact in the TIG areas, thereby enabling very high system reliability based on a relative low frequency of maintenance service required to remove parasitic depositions on the indexer and interior process module surfaces.

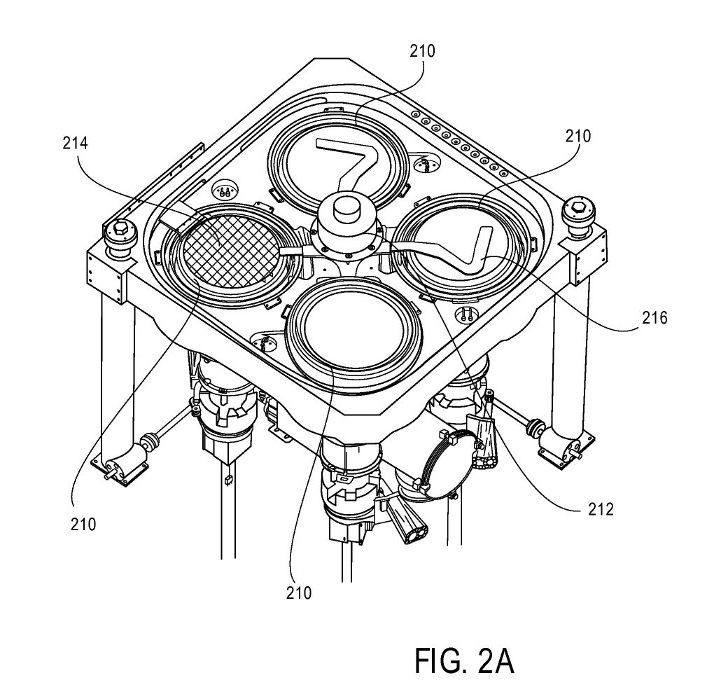

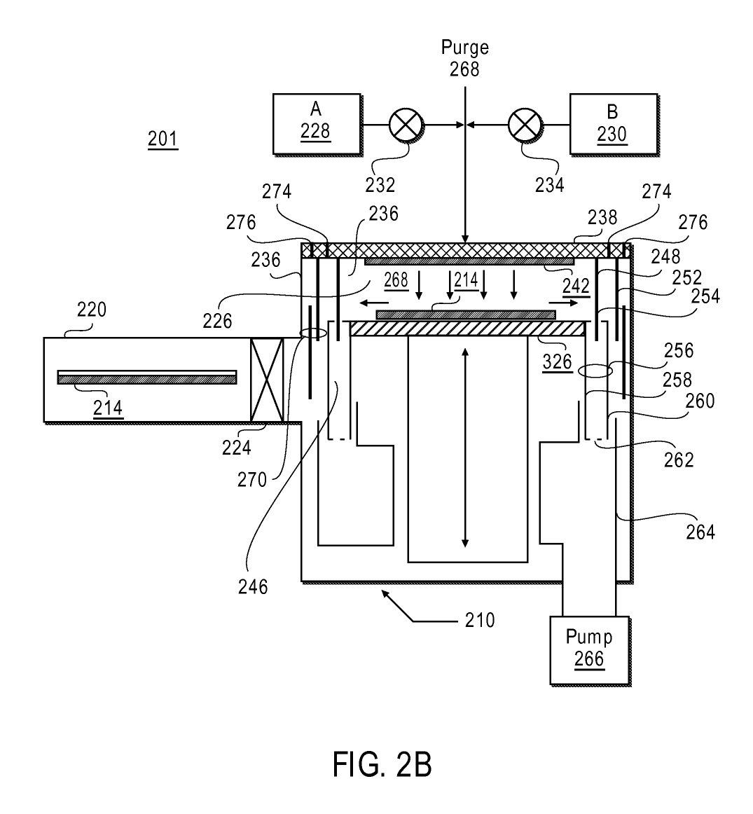

FIG. 2A shows an example of an MSW processing apparatus 200 configured in accordance with an embodiment of the present invention. The MSW system includes four reaction chambers 210 (here only the lower portions of the chambers 210 are shown with the lids removed and the top portions of the heater-susceptors exposed) and the central wafer indexer 212 is also shown. One wafer 214 is shown disposed on an indexer end effector 216 above a vertically moveable heater-susceptor. This is the wafer hand off position. Indexer end effector 216 completes the placement of wafer 214 in reaction chamber 210.

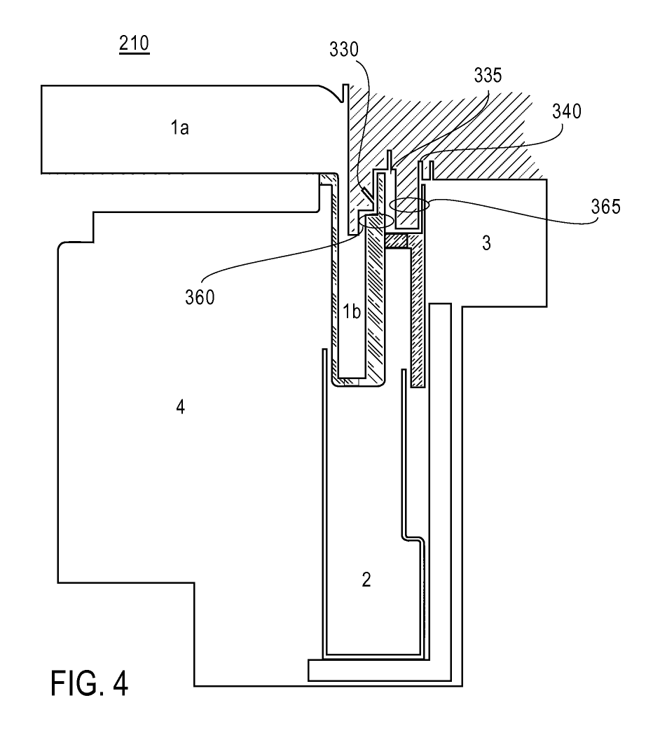

As indicated above, the present invention provides for a combination TIG isolation of a reaction chamber, like reaction chamber 210, consisting of one staircase TIG region and a second TIG region (which may or may not be a staircase TIG region), where at least one of the first and/or second TIG regions are purged to reduce diffusive back transport of unused precursor and byproducts between the reaction volume, the annular flow ring volume or the intermediate volume, and the indexer volume of the MSW system. In such a combination TIG configuration, a second TIG element arrangement is placed outside a first such TIG element arrangement to provide for substantial protection against chemical transport to the indexer area by back-diffusing reactive species, while confining the intermediate volume (see FIG. 4, intermediate volume 2).

A purge may be described with respect to the reduction of diffusive back flow to the indexer region. By reducing the gap space within the TIG region and/or increasing the purge flow, gas velocity through that gap is increased, thereby decreasing the extent of back diffusion. In the case of a single wafer reactor, there is no indexer to protect and the reaction volume is minimal. In the case a single TIG region, a typical back diffusive capability to the indexer is 1E-5, down from the reaction concentration in the reaction volume, while a double or combination TIG configuration with purges provides more than a 1E-10 reduction.

Another advantage of the present design is that it reduces the amount of purge gas diffusing to the process area, which could dilute the reactive species. By adding a second (outer) TIG region and using the purge gas in this TIG region, dilution in the reaction space is not an issue. As a specific example, for typical operating conditions for Hf0₂ film deposition, we have observed a 4% dilution in TEMAH at the edge of the wafer (assuming a homogeneous showerhead for a single TIG region).

The second TIG region was placed outside the first TIG region because its main purpose is to protect the indexer area from back-diffusing reactive species, while confining an “intermediate volume.” See FIG. 4 for an explanation of these different regions. A single TIG region would result in a very large indexer volume to be purged, resulting in high purge flows and a loss in TMF operating efficiency. In the case of a single wafer reactor, there was no indexer to protect and the volume reduction would be minimal, and the second or combination TIG region may or may not be used. The volume required to maintain the TMF effect in this area with a second TIG region is substantially lower than it would be without it (assuming that the effect is proportional to the volume—as can be shown by transient simulation and compared to the case without the second TIG region, while keeping other parameters constant).

FIG. 2B illustrates a cross section of a portion of an exemplary reaction chamber 210 which uses injected precursor gases from axi-centric and axi-symmetric vertical gas distribution modules (GDM) (e.g., using an axi-centric orifice(s) or showerhead). Here, precursors A and B, 228 and 230 respectively, and/or a purge gas 268 are introduced (e.g., under control of valves 232 and 234 in the case of the precursors) via vertical injection into a reaction chamber 210 through a GDM 242. This arrangement allows for radial gas flow over a wafer 214, which is supported in chamber 210 by a heater-susceptor 326, followed by vertical pumping using pump 266. In this case, the dispersion tails are limited to overlap across the radius of the wafer (½ the value of the diameter) which may be advantageous in the case of high back diffusion.

In one embodiment, wafers 214 are introduced into reaction chamber 210b from a wafer handling mechanism 220 through a rectangular slot valve 224 at a particular azimuthal angle and range (θ₁ and Δθ₁) that is on the radius or outer surface of reaction chamber 210 in proximity to the walls of the reactor. In some embodiments, wafer handling mechanism 220 may include central wafer indexer 212 and indexer end effector 216. In some cases, this slot valve and its rectangular passage into the chamber breaks the symmetry of radial gas flow.

Exhaust pump 266 is operable to remove gas from reaction chamber 210 and/or a purge gas flow pathway like those shown in FIG. 4. Exhaust pump 266 may be positioned downstream from radial gas flow 268 and in some cases may be set at an azimuthal angle and range, (θ₂ and Δθ₂), where θ₂ is, in general, not necessarily the same as θ₁.

In the present invention, to minimize the reaction space volume (226 in FIG. 2B), a confined flow path is defined by attaching a guiding annular pumping conduit 246 to the edge of a vertically movable heater-susceptor 326. This design places and confines the flow path as close to the wafer as possible and takes the form of a flow ring 256 that is mechanically attached to the heater-susceptor. Precursor removal periods are greatly reduced and cycle time (CT) is improved (see, e.g., J. Dalton et. al., “High Performance ALD Reactor for Advanced Applications,” presented at ALD2006 International Conference of the American Vacuum Society, Seoul Korea, Jul. 24-26, 2006) by using an annular conduit flow ring that is attached to a movable vertical susceptor (see, e.g., the Doering reference cited above).

The flow ring 256 (with inner surface element 258 ad outer surface element 260) has a conduit with an input orifice 254 at nominally the same height as the vertical susceptor. The lower orifice 262 of the flow ring is below or substantially below the lower edge of the slot valve 224 when the wafer (i.e., the susceptor) is in the processing position. This constraint provides excellent convective flow isolation from the slot valve and improves flow symmetry at the edge of the wafer and just downstream of the wafer surface. The deep flow ring (DFR) 256 then is suitably defined. The outer edge of DFR 256 is placed close to the downstream reactor chamber wall 264, minimizing diffusive back flow to the slot valve 224 and upper outer reactor wall surfaces.

When the vertically movable susceptor with the DFR is elevated into its “up” or processing position (the configuration illustrated in this diagram), the outer surface element 260 of the deep flow ring 256 is placed in close proximity to and overlapped with respect to a bottom of an inner surface element 248 of a “lid-ring” 236 (made up of inner element 248 and an outer element 252) that is attached to inside of the lid 238 of the reactor 210. The basic design is illustrated in FIG. 2B. The inner surface element 254 of the lid ring 236 and the outer surface element 260 of the flow ring 256 define the confining surfaces for the reactant gas flows and provide confinement of the reaction space. Thus, in one embodiment, the DFR at the perimeter of heater-susceptor isolates an outer space of reactor chamber both above and below a wafer position when the heater-susceptor is in a processing position.

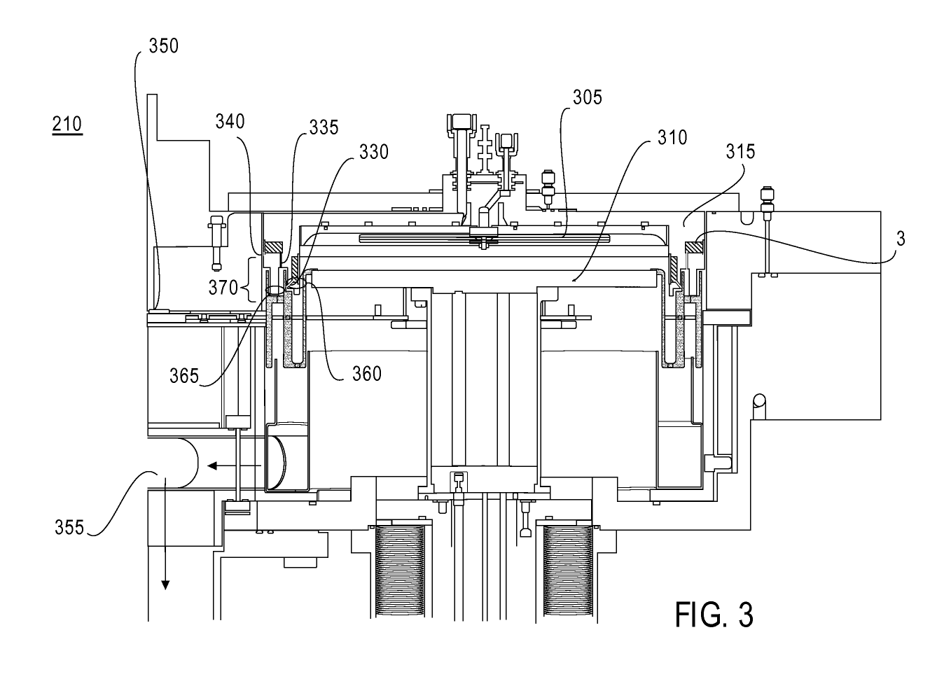

The combination of the DFR 256 and the inner element 248 of the lid ring defines a first TIG region of the reactor chamber. A second TIG region is then defined by the outer element 252 of the lid ring and an outer confinement ring 270. Each gas flow pathway through the first and second TIG regions may be purged by independent purge lines as described in greater detail below with regard to FIGS. 3-6. Either or both of the TIG regions may be characterized by staircase-like overlaps of the elements that make up the TIG regions.

FIG. 3 illustrates a cross section of an exemplary reaction chamber 210, consistent with an embodiment of the present invention. Reaction chamber 210 includes a shower head 305, a wafer platform 310, a lid 315, an indexer volume 3, a first purge line 330, a second purge line 335, a third purge line 340, a chamber/indexer purge 350, an exhaust 355, a first TIG element 360, a second TIG element 365, and a TIG arrangement 370.

Wafer platform 310 may be used to support a wafer during one or more reactions within reaction chamber 210. In some cases, wafer platform 310 may include heater-susceptor 244. Showerhead 305 may be used to diffuse various chemicals or vapors into a volume of reaction chamber 210 and/or onto a wafer, like wafer 214, supported by wafer platform 310. Showerhead 305 may be a GDM, like GDM 242. Lid 315 covers reaction chamber 210 and may include, for example, a portion of TIG arrangement 370 which may, in turn, include a portion of two or more TIG elements such as first TIG element 360 and second TIG element 365. First 360 and second 365 TIG elements may be similar to the first and second TIG elements as shown in FIG. 2B. In some embodiments, TIG arrangement 370 may also include DFR 256. Each gas flow pathway through TIG elements 360 and 365 may be independently purged via, for example, first 330, second 335, and/or third 340 purge lines. First 330, second 335, and/or third 340 purge lines may be similar to first 274 and second 276 purge lines as shown in FIG. 2B. First 330, second 335, and/or third 340 purge lines are independent from one another and in addition to being coupled to a purge gas supply (via independently operated valves or other gas flow controllers) may also be coupled to one or more vacuum pumps (not shown) which may facilitate the purging of the purge lines. Purging through the independent purge lines may be independently time controlled to, for example, optimize operating conditions for reaction chamber 210 or MSW processing apparatus 200. Chamber/indexer purge 350 may facilitate the purging of an indexer volume, reaction chamber 210, or a portion thereof. Exhaust 355 may facilitate the exhausting of one or more substances or gasses from reaction chamber 210 or a portion thereof.

FIG. 4 illustrates a cross section of a portion of reaction chamber 210 and illustrates the use of two TIG elements, like first TIG element 360 or second TIG element 365, one of which includes a staircase arrangement and both of which are purged by independent purge lines like first 330, second 335, and third 340 purge lines. Second TIG element 365 includes a horizontal and a vertical gap, but not a staircase. Being a second TIG region, the isolation requirements are not as tight (as for the first TIG region) as far as back diffusion is concerned, thus allowing the use of a more simplified geometry. Of course, a second TIG configuration may include a staircase arrangement if desired.

In FIG. 4, a process volume of reaction chamber 210 is labeled 1a, an annular flow ring volume is labeled 1b, 2 is an intermediate volume, 3 is an indexer volume, and 4 is a susceptor-heater volume. In one particular implementation, these volumes are approximately as follows: process volume 1a—221 in³; annular flow ring volume 1b—46 in³; intermediate volume 2—340 in³; and indexer volume 3—250 in³. In some cases, indexer volume 3 may be approximately 75% of the size of intermediate volume 2.

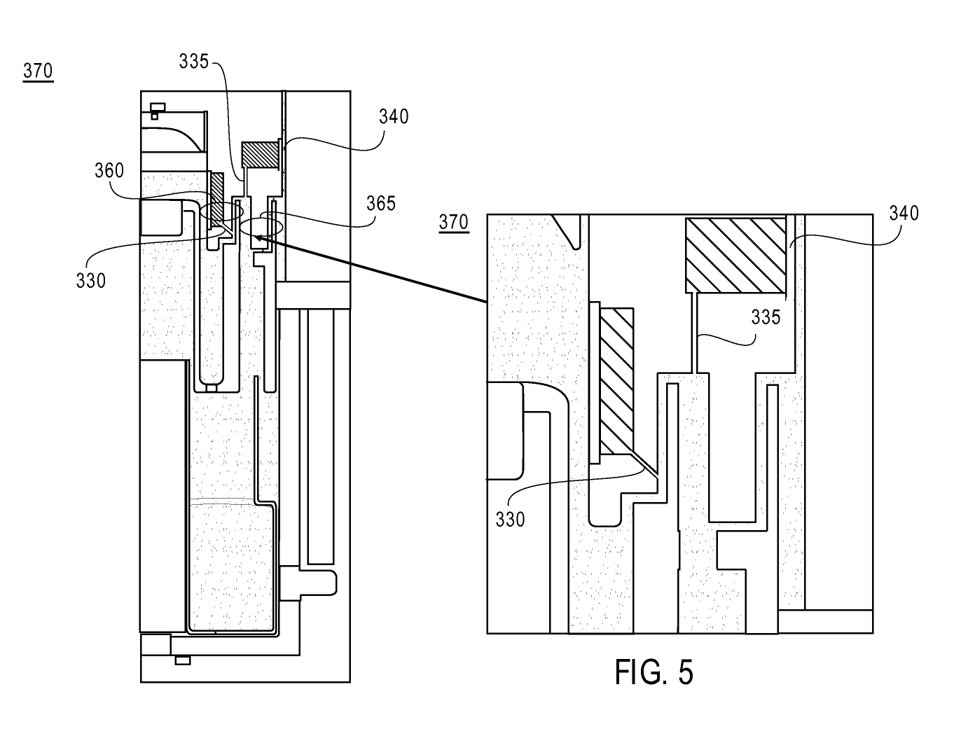

Each of two or more semi-isolated reaction chambers, like reaction chamber 210, may be separated from indexer volume 3. Reaction chambers may be separated by two or more TIG elements like first TIG element 360 or second TIG element 365, either or both of which may include a staircase configuration. Each gas flow pathway through a TIG element may be independently purged through a purge line like first 330, second 335, and third 340 purge lines. FIG. 5 illustrates a close-up view of TIG arrangement 370 and shows first 330, second 335, and third 340 purge lines in more detail.

As indicated above, a purge may be described with respect to reduction of diffusive back flow to indexer volume 3. By reducing a gap between a TIG element like first TIG element 360 or second TIG element 365, and a reaction chamber, like reaction chamber 210, and/or increasing the flow of purge gas through a purge line, gas velocity through that gap is increased, thereby decreasing the extent of back diffusion. The extent of back diffusion can be calculated as follows:

$$x ( y ) = {x}_{o} \cdot exp ( - \frac{u}{D} y ) \qquad ( 1 )$$

where,

u=gas velocity (a function of pressure, temperature, flow rate, and gap cross-section);

D=diffusion coefficient;

Y=distance from the bulk source;

x₀=molar fraction of a given species in the bulk; and

x(y)=molar fraction at position y.

Thus, the molar fraction decay, x(y), along a gap of length y can be determined by this relationship.

As indicated by equation (1), back diffusion can be minimized with high flows and/or tight gaps. As with any diffusion process, chemical species will diffuse from a zone with a higher concentration of a substance or combination of substances to a zone with a lower concentration. This is referred to as back diffusion (or reversed diffusion) because the chemical species move against a flow of gas. A purge within a reaction space, on the other hand, is based on convection, with the chemical species being “pushed” out of the reactor and diluted.

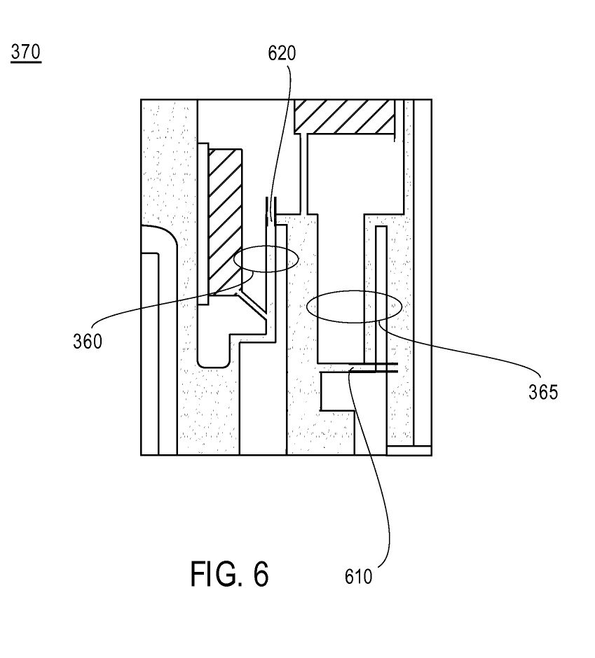

FIG. 6 illustrates horizontal 610 and vertical 620 spacings in TIG arrangement 370. The TIG elements of TIG arrangement 370 have vertical 620 and horizontal 610 conductance spacings such that under different operational process temperatures of the MSW apparatus, changes in horizontal spacing 610 are less than changes in vertical spacing 620. The operation of MSW processing apparatus 200 over a large temperature range requires robust tolerance control. This is the case while maintaining the low TIG conductance to enable low back diffusivity. Since the expansion of the reaction chambers relative to the center of the system (indexer axis) and expansion with respect to the centers of the reaction chambers takes place in the radial direction, the present invention achieves this tolerance control with a staircase TIG arrangement. In one embodiment, horizontal spacing(s) 610 may be smaller than vertical spacing(s) 620. The expansion and contractions of a TIG element like TIG elements 360 and 365, allow a condition where vertical spacing(s) 620 are larger than horizontal spacing(s) 610. Larger vertical spacing(s) 620 can be utilized to accommodate radial expansion and contraction of a TIG element while horizontal spacing(s) 610 may be used to control the low values of conductance. In practice, a combination of effects may be quantitatively utilized to achieve a desired level of tolerance control.

Thus, various embodiments of an MSW processing apparatus have been described. In some embodiments, the MSW processing apparatus may include two or more semi-isolated reaction chambers and a separate indexer volume. The reaction chambers may be separated from one another by isolation regions configured with two or more TIG elements, at least one of which may be configured in a staircase-like fashion. Each gas flow pathway through the TIG elements may be independently purged via an independent purge line.

What is claimed is:

1. A multi single wafer (MSW) processing apparatus comprising two or more semi-isolated reaction chambers and a separate indexer volume, the reaction chambers being separated from one another by isolation regions configured with two or more tongue-in groove (TIG) elements, at least one of which is configured in a staircase-like fashion, and in which each gas flow pathway through the TIG elements is independently purged via independent purge lines.

2. The MSW processing apparatus of claim 1, wherein the at least one TIG element configured in the staircase-like fashion includes vertical and horizontal conductance spacings sized so that a change in the horizontal conductance spacing is less than a change in the vertical conductance spacing under different operational process temperatures of the MSW processing apparatus.

3. The MSW processing apparatus of claim 1, wherein purges through the independent purge lines are independently time controlled.

4. The MSW processing apparatus of claim 1, wherein the at least one TIG element configured in the staircase-like fashion is operable to limit diffusion-backflow of a downstream gas to an outer chamber of the MSW apparatus.

5. The MSW processing apparatus of claim 1, further comprising a pump operable to remove a gas stream through one or more of the independent purge lines.

6. A multi single wafer (MSW) processing apparatus comprising two or more semi-isolated reaction chambers and a separate indexer volume,
the reaction chambers being separated from one another by isolation regions configured with two or more tongue-in groove (TIG) elements, at least one of which is configured in a staircase-like fashion, and in which each flow pathway through the TIG elements is independently purged via independent purge lines, wherein the two or more TIG elements include an inner TIG element and an outer TIG element;
the reaction chambers comprising a vertically movable heater-susceptor coupled to an annular flow ring configured as a gas conduit and having an outlet port extending below a bottom of a wafer transport slot valve of the reaction chamber apparatus when the heater-susceptor is in a processing position, wherein the inner TIG element includes the annular flow ring.

7. A multi single wafer (MSW) processing apparatus comprising two or more semi-isolated reaction chambers and a separate indexer volume,
the reaction chambers being separated from one another by isolation regions configured with two or more tongue-in groove (TIG) elements, at least one of which is configured in a staircase-like fashion, and in which each gas flow pathway through the TIG elements is independently purged via independent purge lines, wherein the two or more TIG elements include an inner TIG element and an outer TIG element;
the reaction chambers comprising a heater-susceptor coupled to an annular flow ring conduit at a perimeter of the heater-susceptor, the annular flow ring defined by inner and outer members and configured to isolate an outer chamber of at least one of the reaction chambers above a wafer position from a confined reaction chamber of the reaction chamber when the heater-susceptor is in a processing position, in which instance an outer member of the annular flow ring is in proximity with a second annular ring attached to a lid of the reaction chamber, the outer member of the annular flow ring and the second annular ring forming at least one of the TIG elements, wherein the inner TIG element includes the annular flow ring.

8. The MSW processing apparatus of claim 7, further comprising a pump operable to remove gas through one or more of the independent purge lines.

9. A multi single wafer (MSW) processing apparatus comprising two or more semi-isolated reaction chambers and a separate indexer volume,
the reaction chambers being separated from one another by isolation regions configured with two or more tongue-in groove (TIG) elements, at least one of which is configured in a staircase-like fashion, and in which each gas flow pathway through the TIG elements is independently purged via independent purge lines, wherein the two or more TIG elements include an inner TIG element and an outer TIG element;
the reaction chambers each comprising a vertically movable susceptor coupled to an annular flow ring conduit at a perimeter of the susceptor, the annular flow ring conduit configured to pass reaction gas effluent to a downstream pump, wherein the inner TIG element includes the annular flow ring.

10. The MSW processing apparatus of claim 9, wherein the annular flow ring includes a lower orifice, the MSW processing apparatus further comprising a downstream baffle located between the lower orifice of the annular flow ring and the downstream pump.

11. The MSW processing apparatus of claim 9, further comprising a second annular ring attached to a lid of the reaction chamber apparatus, the second annular ring being in proximity to an outer member of the annular flow ring conduit when the vertically movable susceptor is in a process position, the second annular ring and the outer member of the annular flow ring conduit forming one of the TIG configurations.

12. The MSW processing apparatus of claim 11, wherein the second annular ring is an inner lid ring, the MSW processing apparatus further comprises an outer lid ring surrounding the TIG configuration formed by the second annular ring and the outer member of the annular flow ring conduit when the vertically movable susceptor is in the process position.

13. The MSW processing apparatus of claim 11, wherein a joint between the second annular ring and the lid is curved.

14. The MSW processing apparatus of claim 11, wherein a joint between the second annular ring and the lid is filleted.
